(19) United States
(12) Patent Application Publication
(10) Pub. No.: US 2023/0197560 A1
(43) Pub. Date: Jun. 22, 2023

(54) THERMOELECTRIC COOLING IN MICROELECTRONICS

(71) Applicant: ADEIA SEMICONDUCTOR BONDING TECHNOLOGIES INC., San Jose, CA (US)

(72) Inventors: Rajesh Katkar, Milpitas, CA (US); Belgacem Haba, Saratoga, CA (US)

(21) Appl. No.: 18/067,668

(22) Filed: Dec. 16, 2022

Related U.S. Application Data
(60) Provisional application No. 63/265,770, filed on Dec. 20, 2021.

(51) Int. Cl. H01L 23/38; H01L 23/00

(52) U.S. Cl. CPC H01L 23/38; H01L 24/08; H01L 2224/08245; H01L 2924/351

(57) ABSTRACT

In some aspects, the disclosed technology provides microelectronic devices which can effectively dissipate heat and manage hot spot. In some embodiments, a disclosed microelectronic device may include a substrate having a thickness in a first direction and at least one thermoelectric unit disposed in or on the substrate. The thermoelectric unit may be configured to transfer heat along a second lateral direction orthogonal to the first direction.

### CROSS-REFERENCE TO RELATED APPLICATIONS

This application claims priority to U.S. Provisional Application No. 63/265,770, filed Dec. 20, 2021, titled “THERMOELECTRIC COOLING IN MICROELECTRONICS”, the content of which is incorporated by reference in its entirety.

### BACKGROUND

### Field

The field relates to dissipating heat and managing hot spots in microelectronics.

### Description of the Related Art

With the miniaturization and the high density integration of electronic components, the heat flux density in microelectronics is increasing. The microelectronic components are typically operated below certain rated temperature to ensure optimal operation. If the heat generated during the operation of microelectronics is not dissipated, distributed or extracted enough, the microelectronics may not operate reliably, its performance may be affected, and it may even shut down or burn out. In particular, thermal dissipation is a serious problem in high-power devices, and the problem worsens with chip stacking.

### BRIEF DESCRIPTION OF THE DRAWINGS

Specific implementations will now be described with reference to the following drawings, which are provided by way of example, and not limitation.

FIG. 1A, FIG. 1B and FIG. 1C schematically illustrate an example microelectronic system according to the disclosed technology.

FIG. 2 schematically illustrates another example microelectronic system according to the disclosed technology.

FIG. 3A and FIG. 3B schematically illustrate alternative thermalelectric units according some embodiments of the disclosed technology.

FIG. 4 schematically illustrates a cross-sectional view of yet another example microelectronic device according to the disclosed technology.

FIG. 5 schematically illustrates a cross-sectional view of yet another example microelectronic device according to the disclosed technology.

FIGS. 6A, 6B, 6C, 6D and 8C schematically illustrate various arrangements of thermoelectric units according to the disclosed technology.

FIG. 7 illustrates an example control circuit for controlling thermoelectric units according to the disclosed technology.

FIG. 8A illustrates stacked thermoelectric elements in an example chip stack. FIG. 8B illustrates stacked thermoelectric elements in another example chip stack.

### DETAILED DESCRIPTION

Microelectronic elements (e.g., dies/chips) can be stacked and bonded to one another to form a device. It is difficult to dissipate heat in a device with chip stacking, especially as chips get thinner. The use of chip joining methods, such as adhesive bonding, flip chip interconnections, etc., can make heat dissipation or transfer towards the heat sink and eventual extraction in the device less effective, as the adhesives may reduce or insulate heat transfer. Moreover, it is difficult to specifically lower the temperature in a desired portion of the device. For example, when packaging stacks of dies, heat dissipation is typically aided by heat sinks at the top of the stack, but extracting heat from lower dies is challenging. Moreover, considering the dimensions of a typical die or die stack, the vertical path length is considerably shorter compared to the path length in the lateral direction for heat extraction purposes. However, embodiments with only vertical thermal transfer traps the heat in the bottom or middle dies which may result in these dies getting significantly hot, effectively limiting stacking implementation to low-power chips. Accordingly, there remains a continuing need for improved techniques to dissipate heat in microelectronic devices.

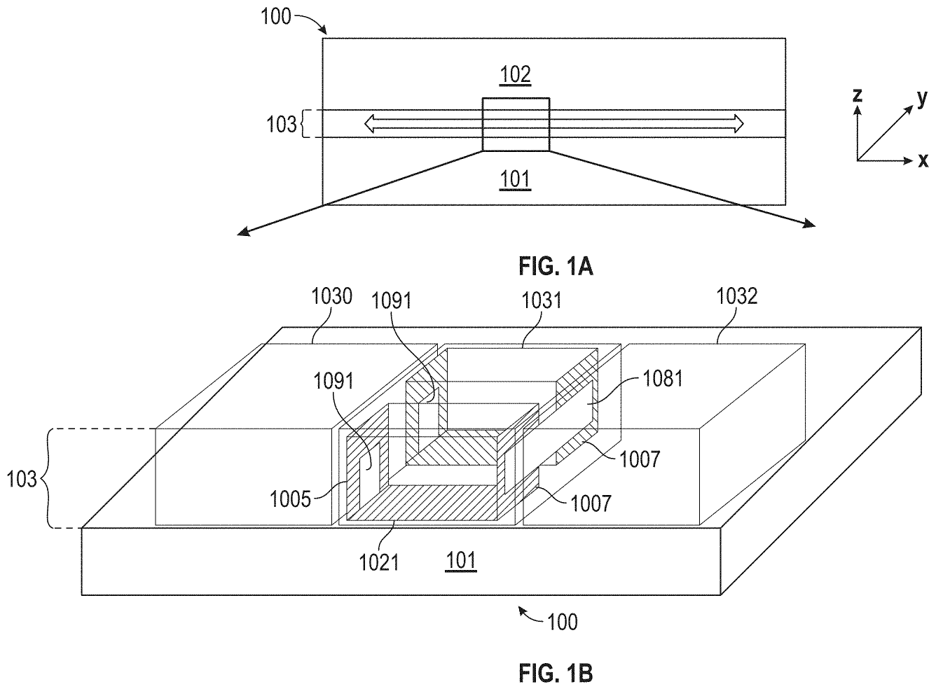

Methods and structures are provided for redirecting thermal flows in die stacks, for example redirecting the heat out from a central location on a die to the periphery of the die or die stack, where heat could be extracted out to heat dissipation structures (e.g., heat sinks/heat pipes), or simply redirecting the heat from one location (e.g., a hot spot) to another location on the die or spread the hotspot to a wider area, or for redirecting heat from a lower die to a heat sink without increasing the temperature of any intervening dies. In some embodiments, a disclosed microelectronic device 100 may include thermoelectric elements 103 that direct heat in a lateral direction (as indicated by the left-right arrow) with respect to a die/chip 101 or 102 (i.e., along the larger dimensions of a die), as illustrated in FIG. 1A. In some embodiments, a disclosed microelectronic device 100 in FIG. 1A may utilize a thermoelectric element 103 having a plurality of cascaded thermoelectric units such as 1030, 1031 and 1032, as shown in FIG. 1B, to laterally transfer heat to the periphery of the device 100 from lower dies (e.g., 101) in the device 100. For example, cascaded thermoelectric units such as 1030, 1031 and 1032 may be disposed in (or on) a substrate (not shown). The substrate may have a smallest dimension along a first direction (e.g., z direction), where the smallest dimension can comprise a thickness of the substrate. In some embodiments, the cascaded thermoelectric units such as 1030, 1031 and 1032 may include Peltier elements comprising N- or P-doped regions formed in the substrate, such as a thermoelectric substrate (e.g., Bi2Te3), as described in U.S. Provisional Application No. 63/265,765, filed Dec. 20, 2021, titled “THERMOELECTRIC COOLING FOR DIE PACKAGES”, the content of which is incorporated by reference in its entirety. In some embodiments, the thickness is no more than 100 microns, or preferably no more than 50 microns. The thermoelectric units 103 may be configured to transfer heat along a second, lateral direction (e.g., x direction) orthogonal to the first direction. The thermoelectric element 103 can help remove heat from the device 100 and actively redirect the heat flow within the device 100, for example actively lower the temperature of a certain chip in the device or of a certain hot spot in a chip. The thermoelectric element 103 may comprise a Peltier element which includes two materials with different Peltier coefficients joined together at a junction. The Peltier element may utilize the Peltier effect to create a net heat flux at the junction of the two different materials when supplied with electrical energy (e.g., a DC electric current), due to the imbalance of the Peltier heat flowing in and out of the junction. In some embodiments, The Peltier element may include a plurality of pairs of p-type and n-type semiconductor pellets, elements or chips connected electrically in series (for example, the p-type and n-type semiconductor pellets in the thermoelectric unit 1031 are connected by way of the electrical connection 1081) and thermally in parallel, such that the charge carriers and heat may all flow in the same direction through the pellets.

In some embodiments, the thermoelectric element 103 is not bonded to other elements of the device 100 by an adhesive or thermal interface material (TIM), which may interfere with heat transfer. Rather, the thermoelectric element 103 may be directly bonded to another element in the device 100, thus improving heat transfer efficiency. For example, a plurality of p-type and n-type semiconductor pellet pairs may be directly bonded to an active chip (e.g., 101 or 102). In some embodiments, the thermoelectric element 103 can be direct hybrid bonded to another element, such that conductive contact(s) and an insulating layer are directly bonded to corresponding conductive contact(s) and insulating layer of the other element. In other embodiments, the thermoelectric element 103 can be directly bonded to the other element with only direct insulator-to-insulator bonds. An active chip (e.g., 101 or 102) may be a die comprising active circuitry, e.g., the active circuitry can include one or more transistors.

In some embodiments, a plurality of p-type and n-type semiconductor thermoelectric pellet pairs can be divided into many groups (such as 1030, 1031 and 1032), and each group may be controlled independently. For example, a sensor (e.g., diode) may be used to measure the temperature at a location in the device. If the temperature at that location is higher than a threshold, the group of thermoelectric pellet or element pairs associated with that location (e.g., 1031) may be activated by applying an electrical current through a pair of electrical contact pins/pads 1091 (for example, each of the electrical contact pins/pads may be applied a voltage of +V or −V). Thus, the temperature in a device may be locally monitored and controlled. The ability to independently operate each group of thermoelectric pellet pairs (such as 1030, 1031 and 1032) may also allow the thermoelectric element 103 to consume less power. The thermoelectric element 103 may be configured for zoned cooling control and local thermal dissipation in response to measured hot spot distribution of a chip. In various embodiments, signals measured by temperature sensors may be used to control the thermoelectric element 103, and the temperature sensors may be located in an active chip (e.g., 101 or 102) to be cooled or within the thermoelectric element 103. In various embodiments, control of the thermoelectric element 103 may be done by in an active chip to be cooled (e.g., 101 or 102), within the thermoelectric element 103, or by an external chip on the system board.

FIG. 1B schematically illustrates an isometric view of a portion of the example microelectronic device 100 shown in FIG. 1A having a lower carrier 101 (which can comprise a die/chip, wafer, interposer, or other suitable element) and a thermoelectric element 103 arranged in a way that can direct heat laterally for the lower element 101. For example, charge carriers can move from hot plates in the XY and YZ planes (1021 and 1005, respectively) to a cold plate in the YZ plane (1007), and heat may be extracted to move in one direction and bend/turn to change the direction for horizontal distribution of thermal energy. In other words, the charge carriers, moving from hot plates in the YZ plane (1005) to a cold plate in the YZ plane (1007), spread the heat from the hotspot in the XY plane (1021), effectively spreading the hot spot and reducing its peak temperature. The thermoelectric element 103 may be actuated by an exemplary control circuit as shown in FIG. 1C. In one example, a thermoelectric element 103 may include a plurality of thermoelectric units such as 1030, 1031 and 1032 (disposed/formed in a Bi₂Te₃ wafer, for example), and a unit 1031 (e.g., having a pair of p-type and n-type semiconductor Peltier pellet) may collect heat from a left unit 1030 (or a right unit 1032, depending on the location of the hot spot) and the bottom chip 101 (and also the top chip 102, in some cases) and send the heat to the cold plate/surface 1007 to the right (or the left, depending on the direction of current provided to the thermoelectric units or pais). In various embodiments, thermoelectric units such as 1030, 1031 and 1032 may be arranged as a X-Y matrix, radially or any other suitable uniform (periodic) or non-uniform distribution based on the thermal map provided during actual experimentation or thermal simulation for the chip or chip stack.

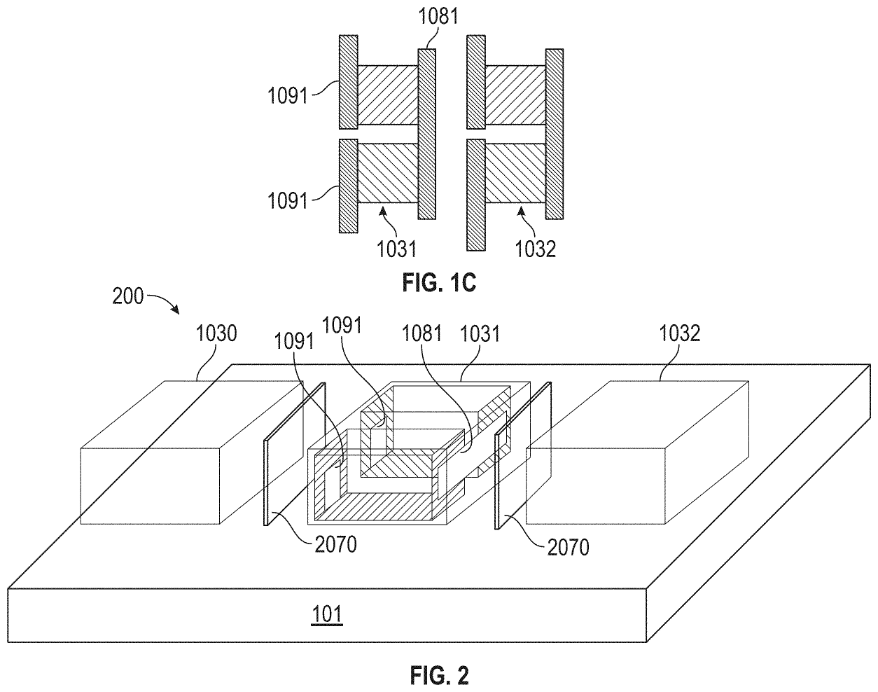

FIG. 2 shows an example microelectronic device 200 similar to that shown in FIG. 1A and FIG. 1B, where like features are referenced by like reference numbers, while each thermoelectric unit (such as 1030, 1031 and 1032) may direct heat bi-directionally, depending on the polarity of applied voltage bias. In the embodiments shown in FIG. 2, thermally conductive but electrically insulating plates 2070 (e.g., formed of TiN, Aluminum Nitride, etc.) may be disposed between two adjacent thermoelectric units (e.g., between 1030 and 1031 and/or between 1031 and 1032) to improve heat transfer between two adjacent thermoelectric units while preventing electrical conduction or current leakage between two adjacent thermoelectric units. FIG. 2 shows the plates 2070 and the thermoelectric units in an exploded view, but in reality there may be no gap between a plate 2070 and its adjacent thermoelectric units.

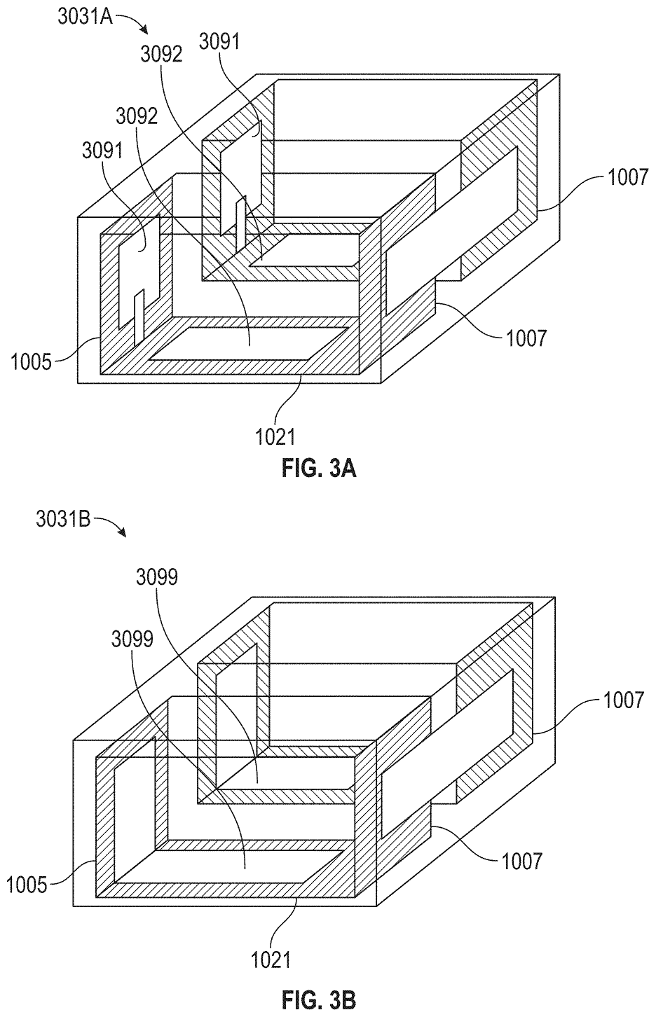

FIG. 3A and FIG. 3B show example thermoelectric units similar to those shown in FIG. 1B, where like features are referenced by like reference numbers. However, as shown in FIG. 3A, in some embodiments of a thermoelectric unit 3031A, separate electrodes (e.g., 3091 and 3092) for vertical and horizontal hot plates (1005 and 1021) may effectively affect the direction of charge carrier flow between one or both hot plates (1005 and/or 1021) and a cold plate 1007. This allows the heat extraction either from the bottom and move laterally or only move laterally (i.e., without any direct active extraction from bottom). In some embodiments, the separate electrodes (e.g., 3091 and 3092, at the top and bottom face, respectively) may be independent and can be used to optimize thermal flow. For example, the voltages applied to the electrodes 3091 and 3092 may all be different. As shown in FIG. 3B, in some embodiments of a thermoelectric unit 3031B, connected electrodes (e.g. 3099) at top and bottom surfaces (1005 and 1021) of the thermoelectric unit 3031B may enable heat extraction from both top and side surfaces of the thermoelectric unit 3031B as the connected electrodes 3099 drive the direction of charge carrier flow to a cold plate 1007. For example, the overall charge carrier flow may be diagonal with respect to the pellets of the thermoelectric unit 3031B.

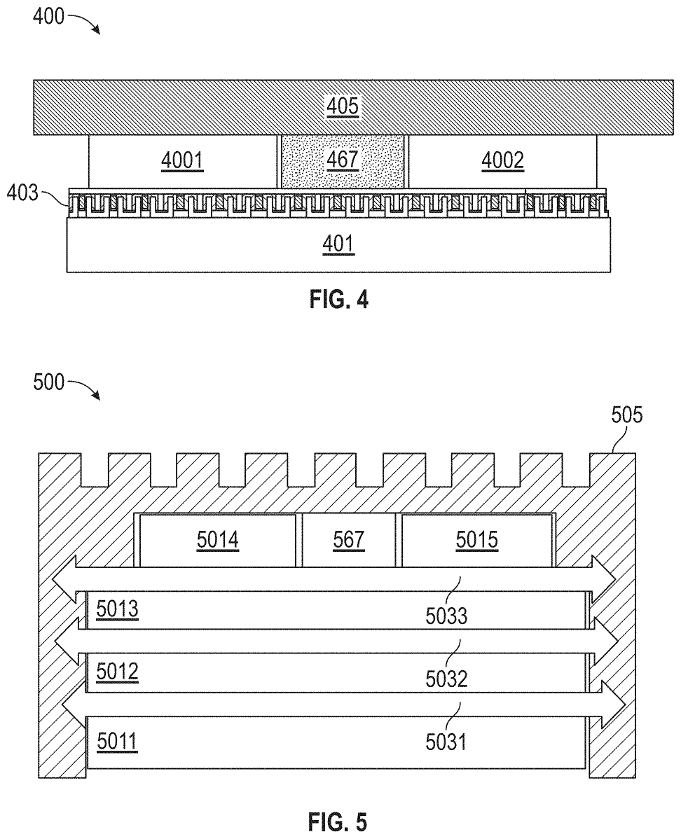

FIG. 4 schematically illustrates a cross-sectional view of an example microelectronic device 400 having stacked dies and a thermoelectric element 403 (as described in connection with any of the previous figures) which directs heat laterally for a bottom chip (401). In some embodiments, the thermoelectric element 403 may include Peltier elements embedded in a substrate, such as a thermoelectric substrate (e.g., Bi2Te3). The Peltier elements may include N- or P-doped regions formed in the substrate, as described in U.S. Provisional Application No. 63/265,765, filed Dec. 20, 2021, titled “THERMOELECTRIC COOLING FOR DIE PACKAGES”, the content of which is incorporated by reference in its entirety. A thermal path 467, or thermally conductive block, may dissipate heat from the thermoelectric element 403 to a heat sink 405 at the top of the die stack. The microelectronic device 400 may further include a few other chips (e.g., 4001 and 4002) that are thermally isolated from the bottom chip (401). The thermoelectric element 403 may be powered by electrical contacts connecting to the bottom chip 401, e.g., to through-substrate vias in the bottom chip 401. In some embodiments, the bottom chip 401 may be in electrical communication with chip 4001 and/or chip 4002 by through-substrate vias. In some examples, heat flow may be directed laterally from the center(s) or interior portions of any of the bottom chip 401, chip 4001 and chip 4002 to the thermal path 467, which redirects the heat vertically to the heat sink 405. In some embodiments, the thermoelectric element 403 can be direct hybrid bonded to another element, such that conductive contact(s) and an insulating layer are directly bonded to corresponding conductive contact(s) and insulating layer of the other element. In other embodiments, the thermoelectric element 403 can be directly bonded to the other element with only direct insulator-to-insulator bonds.

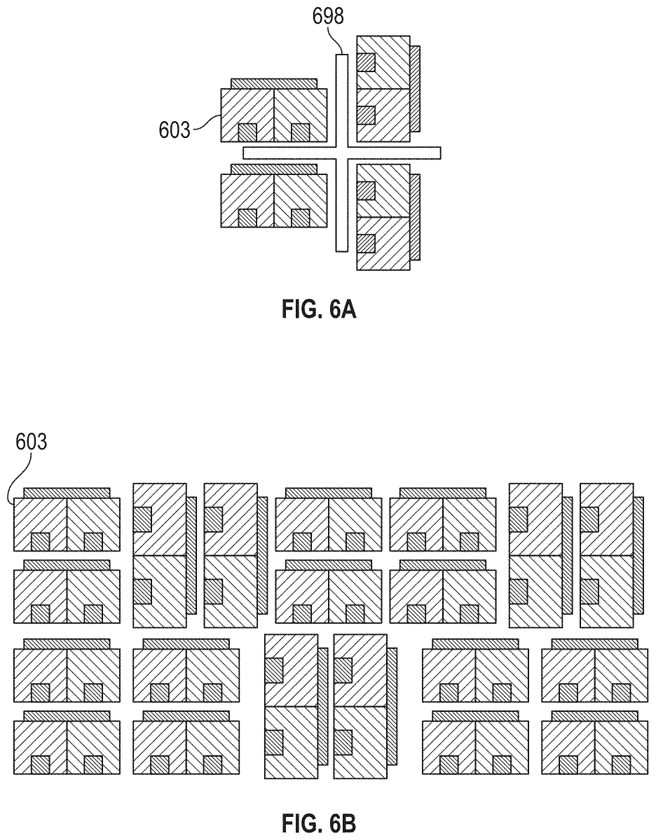

FIG. 5 schematically illustrates a cross-sectional view of an example microelectronic device 500 having stacked chips and thermoelectric elements 5031, 5032 and 5033 which direct heat laterally at one or multiple layers of the device 500. A thermal path 567, or thermally conductive block, may dissipate heat from the thermoelectric element 5033 to a heat sink 505 at the periphery of the device 500. In some embodiments, cascaded thermoelectric units 5031, 5032 and 5033 can dissipate heat all the way to the edge of a chip (e.g., 5011, 5012, 5013, 5014 or 5015) to get extracted (e.g., by heat sink 505, or sideway/edge extraction by a heat spreader or vertical extraction by an exposed surface). In some embodiments, such thermoelectric elements 5031, 5032 and 5033 can distribute/spread/dissipate heat spots, reducing the impact of heat spots on the device performance by reducing the peak temperature. In some embodiments, such thermoelectric elements 5031, 5032 and 5033 may be used for thermal management within a small region compared to the whole chip, for example carry heat from one location to another or distribute or spread a hot spot to a wider area. In some embodiments, the thermoelectric elements 5031, 5032 and 5033 can be direct hybrid bonded to another element, such that conductive contact(s) and an insulating layer are directly bonded to corresponding conductive contact(s) and insulating layer of the other element. In other embodiments, the thermoelectric elements 5031, 5032 and 5033 can be directly bonded to the other element with only direct insulator-to-insulator bonds.

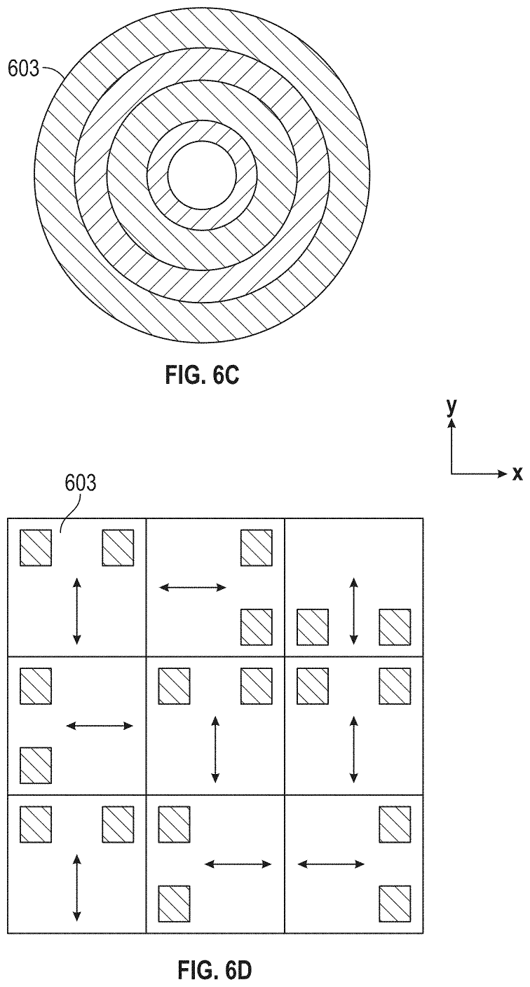

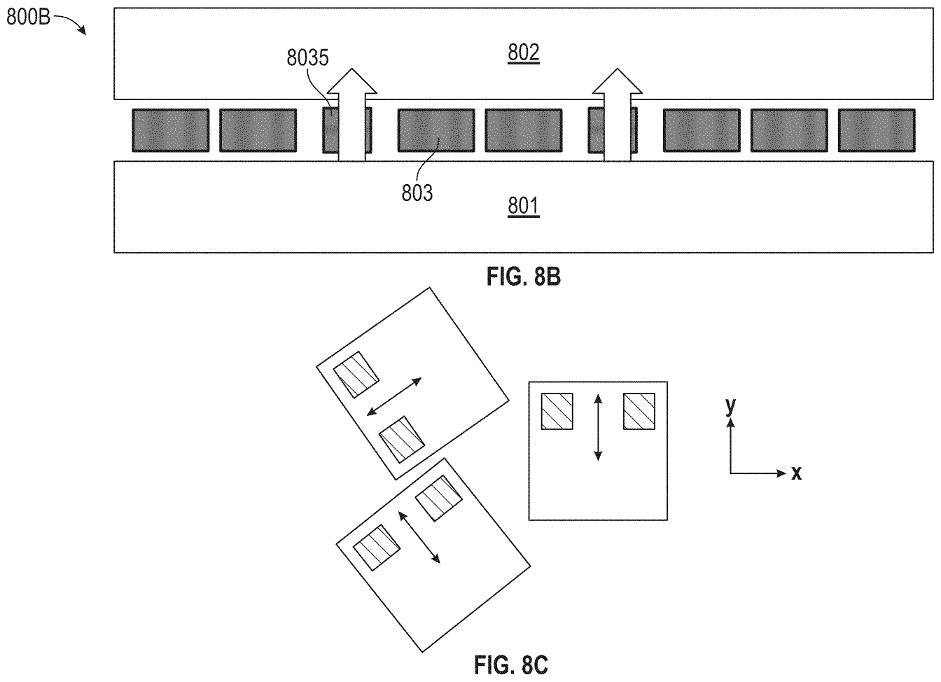

In some embodiments, hot spots in dies may be managed with thermal sensors (e.g., 698) built in the dies or parts of thermoelectric element 603 to detect the hot spots and construct thermal maps. In such embodiments, thermoelectric units 603 can be arranged in various patterns to be able to drive heat flow in a specific direction as optimized by the controller based off of a thermal map. For example, thermoelectric units 603 can be arranged in a grid, as shown in FIG. 6A or FIG. 6B, or radially, as shown in FIG. 6C, and can dissipate heat laterally for a bottom die. Any other suitable uniform/periodic or non-uniform distribution of the Thermoelectric elements may also be arranged. The arrangement may be based on actual thermal maps from an exemplary device or a thermal simulation. The thermoelectric units 603 may be powered through conductive vias within the bottom die or may be powered separately by an external chip. FIG. 6D shows a plan view of thermoelectric units 603 arranged in a plane orthogonal to the direction of the thickness of a wafer in which the thermoelectric units 603 are disposed, the thermoelectric units 603 associated with electrical contacts for optimized positional control and thermal dissipation. In some embodiments, the thickness is no more than 100 microns, or preferably no more than 50 microns. In some examples, the plurality of thermoelectric units 603 shown in FIG. 6D are configured to transfer heat along a pathway within the plane of the thermoelectric units 603, the pathway including at least one turn within the plane. Although shown to carry heat in the XY plane along XX or YY directions (as indicated by the arrows) in FIG. 6D, thermoelectric units can be arranged in other directions, as shown in FIG. 8C.

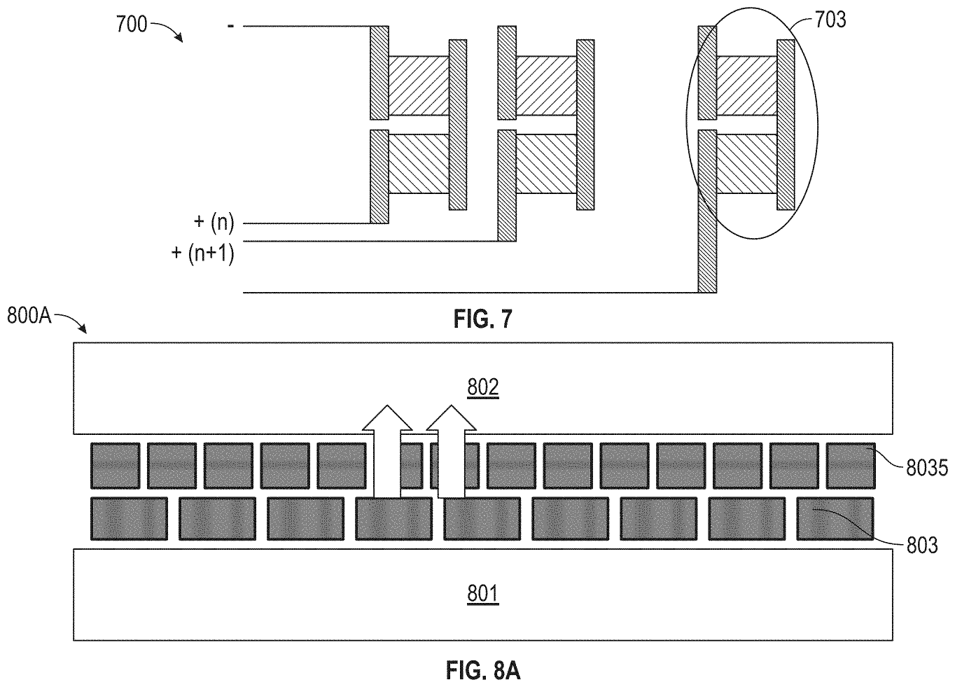

FIG. 7 illustrates an example control circuit/control logic 700 for controlling thermoelectric units 703 and heat dissipation in a disclosed device as described in connection with any of the previous figures. The disclosed control circuit 700 may turn on the units 703 sequentially with a slight delay to drive the heat flow. The control circuit 700 may also activate the units 703 in any suitable optimized pattern (by location or time) for efficient thermal distribution, in some examples. The disclosed control circuit 700 can monitor the heat map of the die (e.g., with thermal sensors internal or external to the thermoelectric element or embedded in chip) and can drive the heat flow by activating one or more groups or zones of thermoelectric unit 703 or pairs and improve the thermal dissipation/distribution by driving heat flow towards one or more optimal locations. In some embodiments, all the thermoelectric units 703 can be connected in parallel, and therefore temperature control at different locations on a die may be managed independently. In some embodiments, a disclosed device may include a combination of several thermoelectric elements 703 connected in parallel to form a block and then several such blocks connected in series. In other embodiments, a disclosed device may include a combination of several thermoelectric elements 703 connected in series to form a block and then several such blocks are connected in parallel. Any suitable distribution of the and combination of thermoelectric elements 703 may be arranged. In some embodiments, a separate independent controller chip may be part of the device chip stack.

FIG. 8A illustrates stacked thermoelectric elements in a chip stack 800A (e.g., including a top die 802 and a bottom die 801). Heat may be extracted upwards in some cases, as indicated by the arrows, e.g., around extreme hot spots, via another layer of thermoelectric element 8035 stacked on a layer of laterally cascaded thermoelectric units 803. FIG. 8B illustrates a chip stack 800B (e.g., including a top die 802 and a bottom die 801) having thermoelectric units arranged in a way that allows extraction of heat both laterally and vertically. For example, some thermoelectric units 8035 that can extract heat upwards (or downwards), as indicated by the arrows, may be embedded within a layer of laterally cascaded thermoelectric units 803. In some embodiments, the disclosed device may further include a thermal barrier/insulator layer to shield the heat going to a top die 802. In some embodiments, the thermoelectric elements 803 and 8035 can be direct hybrid bonded to another element, such that conductive contact(s) and an insulating layer are directly bonded to corresponding conductive contact(s) and insulating layer of the other element. In other embodiments, the thermoelectric elements 803 and 8035 can be directly bonded to the other element with only direct insulator-to-insulator bonds.

### Electronic Elements

A semiconductor element can comprise, for example, any suitable type of integrated device die. For example, the integrated device dies can comprise an electronic component such as an integrated circuit (such as a processor die, a controller die, or a memory die), a microelectromechanical systems (MEMS) die, an optical device, or any other suitable type of device die. In some embodiments, the electronic component can comprise a passive device such as a capacitor, inductor, or other surface-mounted device. Circuitry (such as active components like transistors) can be patterned at or near active surface(s) of the die in various embodiments. The active surface may be on a side of the die which is opposite the backside of the die. The backside may or may not include any active circuitry or passive devices.

An integrated device die can comprise a bonding surface and a back surface opposite the bonding surface. The bonding surface can have a plurality of conductive bond pads including a conductive bond pad, and a non-conductive material proximate to the conductive bond pad. In some embodiments, the conductive bond pads of the integrated device die can be directly bonded to the corresponding conductive pads of the substrate or wafer without an intervening adhesive, and the non-conductive material of the integrated device die can be directly bonded to a portion of the corresponding non-conductive material of the substrate or wafer without an intervening adhesive. Directly bonding without an adhesive is described throughout U.S. Pat. Nos. 7,126,212; 8,153,505; 7,622,324; 7,602,070; 8,163,373; 8,389,378; 7,485,968; 8,735,219; 9,385,024; 9,391,143; 9,431,368; 9,953,941; 9,716,033; 9,852,988; 10,032,068; 10,204,893; 10,434,749; and 10,446,532, the contents of each of which are hereby incorporated by reference herein in their entirety and for all purposes.

### Examples of Direct Bonding Methods and Directly Bonded Structures

Various embodiments disclosed herein relate to directly bonded structures in which two elements can be directly bonded to one another without an intervening adhesive. Two or more electronic elements, which can be semiconductor elements (such as integrated device dies, wafers, etc.), may be stacked on or bonded to one another to form a bonded structure. Conductive contact pads of one element may be electrically connected to corresponding conductive contact pads of another element. Any suitable number of elements can be stacked in the bonded structure. The contact pads may comprise metallic pads formed in a nonconductive bonding region, and may be connected to underlying metallization, such as a redistribution layer (RDL).

In some embodiments, the elements are directly bonded to one another without an adhesive. In various embodiments, a non-conductive or dielectric material of a first element can be directly bonded to a corresponding non-conductive or dielectric field region of a second element without an adhesive. The non-conductive material can be referred to as a nonconductive bonding region or bonding layer of the first element. In some embodiments, the non-conductive material of the first element can be directly bonded to the corresponding non-conductive material of the second element using dielectric-to-dielectric bonding techniques. For example, dielectric-to-dielectric bonds may be formed without an adhesive using the direct bonding techniques disclosed at least in U.S. Pat. Nos. 9,564,414; 9,391,143; and 10,434,749, the entire contents of each of which are incorporated by reference herein in their entirety and for all purposes. Suitable dielectric materials for direct bonding include but are not limited to inorganic dielectrics, such as silicon oxide, silicon nitride, or silicon oxynitride, or can include carbon, such as silicon carbide, silicon oxycarbonitride, silicon carbonitride or diamond-like carbon. In some embodiments, the dielectric materials do not comprise polymer materials, such as epoxy, resin or molding materials.

In various embodiments, hybrid direct bonds can be formed without an intervening adhesive. For example, dielectric bonding surfaces can be polished to a high degree of smoothness. The bonding surfaces can be cleaned and exposed to a plasma and/or etchants to activate the surfaces. In some embodiments, the surfaces can be terminated with a species after activation or during activation (e.g., during the plasma and/or etch processes). Without being limited by theory, in some embodiments, the activation process can be performed to break chemical bonds at the bonding surface, and the termination process can provide additional chemical species at the bonding surface that improves the bonding energy during direct bonding. In some embodiments, the activation and termination are provided in the same step, e.g., a plasma or wet etchant to activate and terminate the surfaces. In other embodiments, the bonding surface can be terminated in a separate treatment to provide the additional species for direct bonding. In various embodiments, the terminating species can comprise nitrogen. Further, in some embodiments, the bonding surfaces can be exposed to fluorine. For example, there may be one or multiple fluorine peaks near layer and/or bonding interfaces. Thus, in the directly bonded structures, the bonding interface between two dielectric materials can comprise a very smooth interface with higher nitrogen content and/or fluorine peaks at the bonding interface. Additional examples of activation and/or termination treatments may be found throughout U.S. Pat. Nos. 9,564,414; 9,391,143; and 10,434,749, the entire contents of each of which are incorporated by reference herein in their entirety and for all purposes.

In various embodiments, conductive contact pads of the first element can also be directly bonded to corresponding conductive contact pads of the second element. For example, a hybrid direct bonding technique can be used to provide conductor-to-conductor direct bonds along a bond interface that includes covalently direct bonded dielectric-to-dielectric surfaces, prepared as described above. In various embodiments, the conductor-to-conductor (e.g., contact pad to contact pad) direct bonds and the dielectric-to-dielectric hybrid bonds can be formed using the direct bonding techniques disclosed at least in U.S. Pat. Nos. 9,716,033 and 9,852,988, the entire contents of each of which are incorporated by reference herein in their entirety and for all purposes.

For example, dielectric bonding surfaces can be prepared and directly bonded to one another without an intervening adhesive as explained above. Conductive contact pads (which may be surrounded by nonconductive dielectric field regions) may also directly bond to one another without an intervening adhesive. In some embodiments, the respective contact pads can be recessed below exterior (e.g., upper) surfaces of the dielectric field or nonconductive bonding regions, for example, recessed by less than 30 nm, less than 20 nm, less than 15 nm, or less than 10 nm, for example, recessed in a range of 2 nm to 20 nm, or in a range of 4 nm to 10 nm. The nonconductive bonding regions can be directly bonded to one another without an adhesive at room temperature in some embodiments in the bonding tool described herein and, subsequently, the bonded structure can be annealed. Annealing can be performed in a separate apparatus. Upon annealing, the contact pads can expand and contact one another to form a metal-to-metal direct bond. Beneficially, the use of hybrid bonding techniques, such as Direct Bond Interconnect, or DBI®, available commercially from Adeia of San Jose, Calif., can enable high density of pads connected across the direct bond interface (e.g., small or fine pitches for regular arrays). In some embodiments, the pitch of the bonding pads, or conductive traces embedded in the bonding surface of one of the bonded elements, may be less 40 microns or less than 10 microns or even less than 2 microns. For some applications the ratio of the pitch of the bonding pads to one of the dimensions of the bonding pad is less than 5, or less than 3 and sometimes desirably less than 2. In other applications the width of the conductive traces embedded in the bonding surface of one of the bonded elements may range between 0.3 to 5 microns. In various embodiments, the contact pads and/or traces can comprise copper, although other metals may be suitable.

Thus, in direct bonding processes, a first element can be directly bonded to a second element without an intervening adhesive. In some arrangements, the first element can comprise a singulated element, such as a singulated integrated device die. In other arrangements, the first element can comprise a carrier or substrate (e.g., a wafer) that includes a plurality (e.g., tens, hundreds, or more) of device regions that, when singulated, form a plurality of integrated device dies. In embodiments described herein, whether a die or a substrate, the first element can be considered a host substrate and is mounted on a support in the bonding tool to receive the second element from a pick-and-place or robotic end effector. The second element of the illustrated embodiments comprises a die. In other arrangements, the second element can comprise a carrier or a flat panel. or substrate (e.g., a wafer).

As explained herein, the first and second elements can be directly bonded to one another without an adhesive, which is different from a deposition process. In one application, a width of the first element in the bonded structure can be similar to a width of the second element. In some other embodiments, a width of the first element in the bonded structure can be different from a width of the second element. The width or area of the larger element in the bonded structure may be at least 10% larger than the width or area of the smaller element. The first and second elements can accordingly comprise non-deposited elements. Further, directly bonded structures, unlike deposited layers, can include a defect region along the bond interface in which nanovoids are present. The nanovoids may be formed due to activation of the bonding surfaces (e.g., exposure to a plasma). As explained above, the bond interface can include concentration of materials from the activation and/or last chemical treatment processes. For example, in embodiments that utilize a nitrogen plasma for activation, a nitrogen peak can be formed at the bond interface. In embodiments that utilize an oxygen plasma for activation, an oxygen peak can be formed at the bond interface. In some embodiments, the bond interface can comprise silicon oxynitride, silicon oxycarbonitride, or silicon carbonitride. As explained herein, the direct bond can comprise a covalent bond, which is stronger than van Der Waals bonds. The bonding layers can also comprise polished surfaces that are planarized to a high degree of smoothness. For example, the bonding layers may have a surface roughness of less than 2 nm root mean square (RMS) per micron, or less than 1 nm RMS per micron.

In various embodiments, metal-to-metal bonds between the contact pads in direct hybrid bonded structures can be joined such that conductive features grains, for example copper grains on the conductive features grow into each other across the bond interface. In some embodiments, the copper can have grains oriented along the 111 crystal plane for improved copper diffusion across the bond interface. The bond interface can extend substantially entirely to at least a portion of the bonded contact pads, such that there is substantially no gap between the nonconductive bonding regions at or near the bonded contact pads. In some embodiments, a barrier layer may be provided under the contact pads (e.g., which may include copper). In other embodiments, however, there may be no barrier layer under the contact pads, for example, as described in US 2019/0096741, which is incorporated by reference herein in its entirety and for all purposes.

In one aspect, the disclosed technology relates to a microelectronic device comprising: a substrate having a thickness in a first direction; and at least one thermoelectric unit disposed in or on the substrate; wherein the thermoelectric unit is configured to transfer heat along a second lateral direction orthogonal to the first direction. In one embodiment, the substrate is directly bonded (e.g., direct hybrid bonded) to a semiconductor element. In one embodiment, the substrate comprises a surface configured for direct hybrid bonding. In one embodiment, the substrate further comprises an opposite surface configured for direct hybrid bonding. In one embodiment, at least one additional thermoelectric unit is disposed in the substrate, the at least one additional thermoelectric unit configured to transfer heat along the second direction. In one embodiment, a thermally conductive plate is disposed between the at least one thermoelectric unit and the at least one additional thermoelectric unit. In one embodiment, the thermally conductive plate is electrically insulating. In one embodiment, the at least one thermoelectric unit is disposed in the substrate.

In one embodiment, at least one additional thermoelectric unit is disposed in the substrate, the at least one additional thermoelectric unit configured to transfer heat along a third direction non-parallel to the second direction and the first direction. In one embodiment, a thermally conductive plate is disposed between the at least one thermoelectric unit and the at least one additional thermoelectric unit. In one embodiment, the thermally conductive plate is electrically insulating. In one embodiment, at least one additional thermoelectric unit is disposed in the substrate, the at least one additional thermoelectric unit configured to transfer heat along the first direction. In one embodiment, a thermally conductive plate is disposed between the at least one thermoelectric unit and the at least one additional thermoelectric unit. In one embodiment, the thermally conductive plate is electrically insulating. In one embodiment, the thickness is no more than 100 microns. In one embodiment, the thermoelectric unit is further configured to transfer heat along the first direction. In one embodiment, the thermoelectric unit is associated with an electrical contact pair configured to drive an electrical current along both the first and/or the second directions in the thermoelectric unit. In one embodiment, the thermoelectric unit is associated with two electrical contact pairs, each electrical contact pair configured to drive an electrical current along one of the first and the second directions in the thermoelectric unit.

In another aspect, the disclosed technology relates to a microelectronic device comprising: a substrate having a thickness in a first direction; and at least one thermoelectric unit disposed in or on the substrate; wherein the thermoelectric unit is configured to transfer heat radially in a plane orthogonal to the first direction. In one embodiment, the substrate is directly bonded (e.g., direct hybrid bonded) to a semiconductor element. In one embodiment, the substrate comprises a surface configured for direct hybrid bonding. In one embodiment, the substrate further comprises an opposite surface configured for direct hybrid bonding. In one embodiment, the thickness is no more than 100 microns. In one embodiment, at least one additional thermoelectric unit is disposed in the substrate, the at least one additional thermoelectric unit configured to transfer heat along the first direction, along a second direction orthogonal to the first direction, or along a third direction non-parallel to the second direction and the first direction. In one embodiment, a thermally conductive structure is disposed between the at least one thermoelectric unit and the at least one additional thermoelectric unit. In one embodiment, the thermally conductive structure is electrically insulating. In one embodiment, the at least one thermoelectric unit is disposed in the substrate.

In another aspect, the disclosed technology relates to a microelectronic device comprising: a lower semiconductor element; a substrate disposed on the semiconductor element, the substrate having a thickness in a first direction; and at least one thermoelectric unit disposed in or on the substrate; wherein the thermoelectric unit is configured to transfer heat laterally along at least a second direction orthogonal to the first direction. In one embodiment, a plurality of thermoelectric units is configured to transfer heat along a pathway within a plane orthogonal to the first direction, the pathway including at least one turn within the plane. In one embodiment, the thermoelectric unit is configured to transfer heat bidirectionally along the second direction. In one embodiment, the thermoelectric unit is configured to transfer heat radially in a plane orthogonal to the first direction. In one embodiment, the thermoelectric unit is configured to transfer heat along a third direction non-parallel to the second direction and the first direction. In one embodiment, the substrate is directly bonded to the semiconductor element without an adhesive. In one embodiment, the semiconductor element comprises silicon, ceramic, Silicon Carbide, Gallium Nitride, or glass. In one embodiment, the semiconductor element is devoid of active circuitry. In one embodiment, the at least one thermoelectric unit is disposed in the substrate.

In one embodiment, the semiconductor element comprises a integrated device die having active circuitry. In one embodiment, the interface between the semiconductor element and the substrate comprises conductor-to-conductor direct bonds. In one embodiment, the interface between the semiconductor element and the substrate further comprises non-conductor to non-conductor direct bonds. In one embodiment, a heat sink is disposed over at least the substrate. In one embodiment, heat is dissipated from the substrate to the heat sink during operation of the thermoelectric unit. In one embodiment, a thermally conductive element is disposed between the substrate and the heat sink. In one embodiment, the thermally conductive element is devoid of active circuitry. In one embodiment, the thermally conductive element comprises silicon or ceramic. In one embodiment, the substrate is directly bonded to the thermally conductive element without an adhesive. In one embodiment, the interface between the substrate and the thermally conductive element comprises dielectric-to-dielectric direct bonds. In one embodiment, heat is dissipated from the substrate to the heat sink through the thermally conductive element during operation of the thermoelectric unit.

In another aspect, the disclosed technology relates to a microelectronic device comprising: a first integrated device die; a substrate disposed on the first integrated device die; at least one thermoelectric unit disposed in or on the substrate; and a second integrated device die disposed on the substrate; wherein the thermoelectric unit transfers heat laterally from at least one of the first and second integrated device dies. In one embodiment, the substrate has a thickness in a first direction, wherein the thermoelectric unit is configured to transfer heat along at least a second direction orthogonal to the first direction. In one embodiment, the thermoelectric unit is electrically connected with through-substrate vias in the first integrated device die such that the thermoelectric unit is controlled by the first integrated device die. In one embodiment, the substrate is directly bonded to the first integrated device die without an adhesive. In one embodiment, the second integrated device die is directly bonded to the substrate without an adhesive. In one embodiment, a heat sink is disposed over at least the substrate. In one embodiment, a thermally conductive element is disposed between the substrate and the heat sink. In one embodiment, the thermoelectric unit transfers heat laterally from the first and second integrated device dies to a thermal path that vertically transfers heat to the heat sink. In one embodiment, a third integrated device die is disposed on the substrate. In one embodiment, the second integrated device die or a third integrated device die is electrically connected to the at least one thermoelectric unit. In one embodiment, the first and second integrated device dies are in electrical communication by way of through-substrate vias. In one embodiment, the at least one thermoelectric unit is disposed in the substrate.

In another aspect, the disclosed technology relates to a microelectronic device comprising: a semiconductor element; a substrate disposed on the semiconductor element, the substrate having a thickness in a first direction; and a plurality of thermoelectric units disposed in the substrate; wherein a first portion of thermoelectric units are configured to transfer heat along the first direction, and a second portion of thermoelectric units are configured to transfer heat laterally along a second direction orthogonal to the first direction. In one embodiment, the first portion of thermoelectric units are disposed on the second portion of thermoelectric units. In one embodiment, both the first and the second portion of thermoelectric units are disposed on the semiconductor element. In one embodiment, the thermoelectric unit is electrically connected with through-substrate vias in the semiconductor element. In one embodiment, the substrate is directly bonded to the semiconductor element without an adhesive. In one embodiment, the thermoelectric unit is electrically connected with through-substrate vias in the semiconductor element.

In another aspect, the disclosed technology relates to a microelectronic device comprising: an semiconductor element; a substrate disposed on the semiconductor element; a plurality of thermoelectric units disposed in the substrate; and a plurality of temperature sensors configured to detect a local temperature in the semiconductor element. In one embodiment, the plurality of thermoelectric units are configured to transfer heat along a pathway within a plane orthogonal to a direction along the thickness of the substrate, the pathway including at least one turn within the plane. In one embodiment, the thermoelectric units are configured to transfer heat away from a local hot spot. In one embodiment, the substrate has a thickness in a first direction, wherein the thermoelectric units are configured to transfer heat along a second direction orthogonal to the first direction. In one embodiment, the plurality of temperature sensors are disposed in the semiconductor element or the substrate. In one embodiment, the microelectronic device further comprises a plurality of electrical contact pairs, each electrical contact pair independently controlling a portion of the plurality of thermoelectric units. In one embodiment, the thermoelectric units are actuated by the semiconductor element, the substrate, or an external chip.

In another aspect, the disclosed technology relates to a microelectronic device comprising: a semiconductor element; a substrate disposed on the semiconductor element; and a plurality of thermoelectric units disposed in the substrate, wherein the substrate is configured for zoned control of cooling the semiconductor element by independently controlling subgroups of the plurality of thermoelectric units. In one embodiment, the substrate has a thickness in a first direction, wherein the thermoelectric units are configured to transfer heat along a second direction orthogonal to the first direction. In one embodiment, a plurality of temperature sensors is disposed in the semiconductor element or the substrate, wherein each temperature sensor is associated with electrical contacts for actuating a portion of the thermoelectric units. In one embodiment, the microelectronic device further comprises a plurality of electrical contact pairs, each electrical contact pair independently controlling a portion of the thermoelectric units. In one embodiment, the thermoelectric units are actuated by the semiconductor element, the substrate, or an external chip.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A microelectronic device comprising:
a substrate having a thickness in a first direction; and
at least one thermoelectric unit disposed in or on the substrate;
wherein the thermoelectric unit is configured to transfer heat along a second lateral direction orthogonal to the first direction.

2. The microelectronic device of claim 1, wherein the substrate is directly bonded to a semiconductor element.

3. The microelectronic device of claim 2, wherein the substrate is direct hybrid bonded a semiconductor element.

4. The microelectronic device of claim 1, wherein the substrate comprises a surface configured for direct hybrid bonding.

5. The microelectronic device of claim 2, wherein the substrate further comprises an opposite surface configured for direct hybrid bonding.

6. The microelectronic device of claim 1, further comprising at least one additional thermoelectric unit disposed in the substrate, the at least one additional thermoelectric unit configured to transfer heat along the second direction.

7. The microelectronic device of claim 6, further comprising a thermally conductive plate disposed between the at least one thermoelectric unit and the at least one additional thermoelectric unit.

8. The microelectronic device of claim 7, wherein the thermally conductive plate is electrically insulating.

9. A microelectronic device comprising:
a substrate having a thickness in a first direction; and
at least one thermoelectric unit disposed in or on the substrate;
wherein the thermoelectric unit is configured to transfer heat radially in a plane orthogonal to the first direction.

10. The microelectronic device of claim 9, wherein the substrate is directly bonded to a semiconductor element.

11. The microelectronic device of claim 9, wherein the substrate comprises a surface configured for direct hybrid bonding.

12. The microelectronic device of claim 11, wherein the substrate further comprises an opposite surface configured for direct hybrid bonding.

13. The microelectronic device of claim 9, wherein the thickness is no more than 100 microns.

14. The microelectronic device of claim 9, further comprising at least one additional thermoelectric unit disposed in the substrate, the at least one additional thermoelectric unit configured to transfer heat along the first direction, along a second direction orthogonal to the first direction, or along a third direction non-parallel to the second direction and the first direction.

15. The microelectronic device of claim 14, further comprising a thermally conductive structure disposed between the at least one thermoelectric unit and the at least one additional thermoelectric unit.

16. A microelectronic device comprising:
a semiconductor element;
a substrate disposed on the semiconductor element; and
a plurality of thermoelectric units disposed in the substrate,
wherein the substrate is configured for zoned control of cooling the semiconductor element by independently controlling subgroups of the plurality of thermoelectric units.

17. The microelectronic device of claim 16, wherein the substrate has a thickness in a first direction, wherein the thermoelectric units are configured to transfer heat along a second direction orthogonal to the first direction.

18. The microelectronic device of claim 16, further comprising a plurality of temperature sensors disposed in the semiconductor element or the substrate, wherein each temperature sensor is associated with electrical contacts for actuating a portion of the thermoelectric units.

19. The microelectronic device of claim 16, further comprising a plurality of electrical contact pairs, each electrical contact pair independently controlling a portion of the thermoelectric units.

20. The microelectronic device of claim 16, wherein the thermoelectric units are actuated by the semiconductor element, the substrate, or an external chip.
